(19) United States
(12) Patent Application Publication
(10) Pub. No.: US 2022/0243150 A1
(43) Pub. Date: Aug. 4, 2022

(54) Cleaning Composition For Semiconductor Substrates

(71) Applicant: Versum Materials US, LLC, Tempe, AZ (US)

(72) Inventors: LILI WANG, Chandler, AZ (US); AIPING WU, Chandler, AZ (US); LAISHENG SUN, Gilbert, AZ (US); YI-CHIA LEE, Chupei City (TW); YUANMEI CAO, Carmel, IN (US)

(73) Assignee: Versum Materials US, LLC, Tempe, AZ (US)

(21) Appl. No.: 17/596,199

(22) PCT Filed: Jun. 15, 2020
(86) PCT No.: PCT/US2020/037745

§ 371 Date: Dec. 3, 2021

Related U.S. Application Data
(60) Provisional application No. 62/863,541, filed on Jun. 19, 2019.

(51) Int. Cl. C11D 11/00; G03F 7/42; H01L 21/02; C11D 7/32; C11D 7/26; C11D 7/50

(52) U.S. Cl. CPC C11D 11/0047; G03F 7/425; H01L 21/02052; C11D 7/5004; C11D 7/263; C11D 7/265; C11D 7/3218

(57) ABSTRACT

Compositions and methods useful for removing residue and photoresist from a semiconductor substrate comprising: from about 5 to about 60% by wt. of water; from about 10 to about 90% by wt. of a water-miscible organic solvent; from about 5 to about 90% by wt. of at least one alkanolamine; from about 0.05 to about 20% by wt. of at least one polyfunctional organic acid; and from about 0.1 to about 10% by wt. of at least one phenol-type corrosion inhibitor, wherein the composition is substantially free of hydroxylamine.

### BACKGROUND OF THE INVENTION

The present invention provides cleaning compositions that can be used for a variety of applications including, for example, removing unwanted resist films, post-etch, and post-ash residue on a semiconductor substrate. In particular, the present invention provides cleaning compositions that are particularly useful for removing photoresist, etch residue, and anti-reflective coatings (ARC), are free of hydroxylamine, and exhibit excellent compatability with materials such as aluminum-copper alloys, aluminum nitride, tungsten, aluminum oxide, and/or other materials, such as, Al, Ti, TiN, Ta, TaN, or a silicide, such as, for example, a silicide of tungsten, or dielectrics.

The background of the present invention will be described in connection with its use in cleaning applications involving the manufacture of integrated circuits. It should be understood, however, that the use of the present invention has wider applicability as described hereinafter.

In the manufacture of integrated circuits, it is sometimes necessary to etch openings or other geometries in a thin film deposited or grown on the surface of silicon, gallium arsenide, glass, or other substrate located on an in-process integrated circuit wafer. Present methods for etching such a film require that the film be exposed to a chemical etching agent to remove portions of the film. The particular etching agent used to remove the portions of the film depends upon the nature of the film. In the case of an oxide film, for example, the etching agent may be hydrofluoric acid. In the case of a polysilicon film, it will typically be a mixture of hydrofluoric acid, nitric acid and acetic acid for isotropic silicon etch.

In order to assure that only desired portions of the film are removed, a photolithography process is used, through which a pattern in a computer drafted photo mask is transferred to the surface of the film. The mask serves to identify the areas of the film which are to be selectively treated. This pattern is formed with a photoresist material, which is a light sensitive material spun onto the in-process integrated circuit wafer in a thin film and exposed to high intensity radiation projected through the photo mask. The exposed or unexposed photoresist material, depending on its composition, is typically dissolved with developers, leaving a pattern which allows etching to take place in the selected areas, while preventing etching in other areas. Positive-type resists, for example, have been extensively used as masking materials to delineate patterns on a substrate that, when etching occurs, will become vias, trenches, contact holes, etc.

Increasingly, a dry etching process such as, for example, plasma etching, reactive ion etching, or ion milling is used to attack the photoresist-unprotected area of the substrate to form the vias, trenches, contact holes, etc. As a result of the plasma etching process, photoresist, etching gas and etched material by-products are deposited as residues around or on the sidewall of the etched openings on the substrate.

Such dry etching processes also typically render the photoresist extremely difficult to remove. For example, in complex semiconductor devices such as advanced DRAMS and logic devices with multiple layers of back end lines of interconnect wiring, reactive ion etching (RIE) is used to produce vias through the interlayer dielectric to provide contact between one level of silicon, silicide or metal wiring to the next level of wiring. These vias typically expose, one or more of Al, AlCu, Cu, Ti, TiN, Ta, TaN, silicon or a silicide such as, for example, a silicide of tungsten, titanium or cobalt. The RIE process leaves a residue on the involved substrate comprising a complex mixture that may include, for example, re-sputtered oxide material, polymeric material derived from the etch gas, and organic material from the resist used to delineate the vias.

Additionally, following the termination of the etching step, the photoresist and etch residues must be removed from the protected area of the wafer so that the final finishing operation can take place. This can be accomplished in a plasma “ashing” step by the use of suitable plasma ashing gases. This typically occurs at high temperatures, for example, above 200° C. Ashing converts most of the organic residues to volatile species, but leaves behind on the substrate a predominantly inorganic residue. Such residue typically remains not only on the surface of the substrate, but also on inside walls of vias that may be present. As a result, ash-treated substrates are often treated with a cleaning composition typically referred to as a “liquid stripping composition” or “cleaning composition” to remove the highly adherent residue from the substrate. Finding a suitable cleaning composition for removal of this residue without adversely affecting, e.g., corroding, dissolving or dulling, the metal circuitry has also proven problematic. Failure to completely remove or neutralize the residue can result in discontinuances in the circuitry wiring and undesirable increases in electrical resistance.

Dry ashing of photoresist using plasma applied subsequently to an etch plasma leads to degradation of low-k material. Therefore, ashing processes is not suitable to clean the photoresist due to either the compatibility of other layers such as metal layers AlCu or a process requiring no ashing due to integration scheme. Alternative wet chemistry is used to remove photoresist film based on dissolution of photoresist in compositions. The wet stripping is capable of complete removal of the photoresist layer without damaging other layers, either metal layers, such as, AlCu or AlN or dielectic layers.

Cleaning compositions used to remove photoresists and other residue from semiconductor substrates typically contain hydroxylamine (HA) and/or quaternary ammonium hydroxide. The use of HA raises serious environmental concern due to its potentially explosive nature and, accordingly, some end users have imposed severe restrictions on HA usage. In the art, a problem with compositions that are free of HA typically exhibit decreased photoresist removal performance.

In addition to the cleaning performance, the cleaning compositions of this invention must have high compatibibility with new or additional materials present in the structures on the semiconductor substrates, such as, aluminum nitride, aluminum-copper alloys and dielectric materials. High compatibility means that the cleaning compositions will cause no or only limited etch damage to those materials and therefore no or only limited etch damage to the structures made of those materials. Continuously improving the cleaning compositions to improve the cleaning performance while reducing etching of the materials on the substrate is necessary to increase chip performance as the structures thereon continue to shrink.

Therefore, there is a need in the art for a cleaning composition, with high compatibility requirements to aluminum-copper alloys, aluminum nitride, tungsten, aluminum oxide, and dielectrics, that is free of hydroxylamine, and that is non-toxic and environmentally friendly for various back-end cleaning operations including stripping photoresist and plasma ash residue such as, for example, those generated by plasma processes, without suffering from the above-identified drawbacks.

### BRIEF SUMMARY OF THE INVENTION

The present invention satisfies this need by providing a composition useful for removing residue and photoresist from a semiconductor substrate with minimum etch of aluminum-copper alloys, aluminum nitride and tungsten, the composition comprising, consisting essentially of, or consisting of: from about 5 to about 60% by wt. of water; from about 10 to about 90% by wt. at least one water-miscible organic solvent selected from pyrrolidones, sulfonyl-containing solvents, acetamides, glycol ethers, polyols, cyclic alcohols, and mixtures thereof; from about 5 to about 90% by wt. of at least one alkanolamine; from about 0.05 to about 20% by wt. of at least one polyfunctional organic acid; and from about 0.1 to about 10% by wt. of at least one phenol-type corrosion inhibitor, wherein the composition is free of hydroxylamine.

In one aspect, the the at least one water-miscible organic solvent is selected from, or selected from the group consisting of N-methyl pyrrolidone (NMP), sulfolane, DMSO, dimethylacetamide (DMAC), diproylene glycol monomethyl ether(DPGME), diethylene glycol monomethyl ether (DEGME), butyl digycol (BDG), 3-methoxyl methyl butanol (MMB), tripropylene glycol methyl ether, propylene glycol propyl ether and diethylene gycol n-butyl ether, ethylene glycol, propylene glycol (PG), 1,4 butandiol, tetrahydrofurfyl alcohol and benzyl alcohol, and mixtures thereof; from about 5 to about 90% by wt. of at least one alkanolamine; from about 0.1 to about 20% by wt. of at least one polyfunctional organic acid; and from about 0.1 to about 10% by wt. of at least one phenol-type inhibitors, such as, at least one selected from, or selected from the group consisting of, catechol, 2,3-dihydroxybenzoic acid, and resorcinol, or selected from gallic acid, or t-butyl catechol, wherein the composition is free of hydroxylamine. In another aspect, the water miscible solvent may be selected from N-methyl pyrrolidone (NMP), sulfolane, DMSO, dimethylacetamide (DMAC), diproylene glycol monomethyl ether(DPGME), diethylene glycol monomethyl ether (DEGME), butyl digycol (BDG), 3-methoxyl methyl butanol (MMB), ethylene glycol, propylene glycol (PG), 1,4 butandiol, tetrahydrofurfyl alcohol and benzyl alcohol.

In another aspect, the present invention provides a method for removing photoresist or residue from a substrate comprising one or more of aluminum, aluminum copper alloy, tunsgen, aluminum nitride, silicon oxide and silicon, the method comprising the steps of: contacting the substrate with a composition useful for removing residue and photoresist from a semiconductor substrate comprising, consisting essentially of, or consisting of: from about 5 to about 60% by wt. of water; from about 10 to about 90% by wt. of a water-miscible organic solvent selected from, or selected from the group consisting of, pyrrolidones, sulfonyl-containing solvents, acetamides, glycol ethers, polyols, cyclic alcohols, and mixtures thereof, which may be selected from N-methyl pyrrolidone (NMP), dimethyl sulfoxide (DMSO), sulfolane, dimethylacetamide (DMAC), diproylene glycol monomethyl ether (DPGME), diethylene glycol monomethyl ether (DEGME), butyl digycol (BDG), 3-methoxyl methyl butanol (MMB), tripropylene glycol methyl ether, propylene glycol propyl ether and diethylene gycol n-butyl ether, ethylene glycol, propylene glycol (PG), 1,4 butanediol, tetrahydrofurfyl alcohol and benzyl alcohol, and mixtures thereof; or may be selected from N-methyl pyrrolidone (NMP), dimethyl sulfoxide (DMSO), dimethylacetamide (DMAC), diproylene glycol monomethyl ether (DPGME), ethylene glycol, propylene glycol (PG) and mixtures thereof; from about 5 to about 90% by wt. of at least one alkanolamine; from about 0.05 to about 20% by wt. or from about 0.1 to about 20% by wt. of at least one polyfunctional organic acid; and from about 0.1 to about 10% by wt. of at least one phenol-type inhibitor which may be selected from, or selected from the group consisting of, gallic acid, t-butyl catechol, catechol, 2,3-dihydroxybenzoic acid, and resorcinol, wherein the composition is free of hydroxylamine; rinsing the substrate with water; and drying the substrate.

Compositions of the present invention have excellent cleaning properties, are less toxic, and are more environmentally acceptable than compositions that are currently being used in the semiconductor industry. Moreover, compositions of the present invention demonstrate compatibility with various metallic and dielectric materials commonly found on semiconductor substrates.

### DETAILED DESCRIPTION OF THE INVENTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention. The use of the term “comprising” in the specification and the claims includes the more narrow language of “consisting essentially of” and “consisting of.”

Embodiments of this invention are described herein, including the best mode known to the inventors for carrying out the invention. Variations of those embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

For ease of reference, “microelectronic device” or “semiconductor substrates” corresponds to wafers, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly.

As defined herein, “low-k dielectric material” or “dielectric” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

“Substantially free” is defined herein as less than 0.001 wt. %. “Substantially free” also includes 0.000 wt. %. The term “free of” means 0.000 wt. %.

As used herein, “about” is intended to correspond to ±5% of the stated value.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. The specified weight percents are based on the total weight for the composition and total 100%.

Cleaning formulations are needed for Al BEOL (back-end-of the-line) cleaning of ashed and unashed substrates. It is well known to those in the art that a key property of an effective cleaner is its ability to attack and dissolve post-etch and post-ash residues without substantially attacking the underlying interconnect dielectric or metals; the selection of corrosion inhibitor may be the key to controlling the metal etch rate. The metals that may be present may be aluminum-containing metals, such as aluminum, aluminum-copper alloys, aluminum nitride, aluminum oxide, or titanium containing metals, such as Ti, TiN, or tantalum containing metals, such as, Ta, TaN, or tungsten-containing metal such as tungsten, or silicide of tungsten; or other silicides. Dielectrics may be present thereon too. Of particular interest are Al, AlNi, AlCu, W, TiN and Ti.

In a broad aspect, the present invention provides a composition whose components are present in amounts that effectively remove residue or photoresist from a substrate such as, for example, a semiconductor substrate. In applications concerning semiconductor substrates, such residues include, for example, photoresist, photoresist residues, ash residues, and etch residues such as, for example, residues caused by reactive ion etching. Moreover, a semiconductor substrate also includes metal, silicon, silicate and/or inter-level dielectric material such as deposited silicon oxides, which will also come into contact with the cleaning composition. Typical metals include titanium, titanium nitride, tantalum, tungsten, tantalum nitride, aluminum, aluminum alloys, and aluminum nitride. The cleaning composition of the present invention is compatible with such materials as they exhibit a low metal and/or dielectric etch rate.

The cleaning compositions of the present invention comprise, consist essentially of, or consist of: from about 5 to about 60% by wt. of water; from about 10 to about 90% by wt. of a water-miscible organic solvent selected from, or selected from the group consisting of, pyrrolidones, such as, N-methyl pyrrolidone (NMP); sulfonyl-containing solvents, such as, dimethyl sulfoxide (DMSO) and sulfolane; acetamides, such as, dimethylacetamide (DMAC); glycol ethers, such as, diproylene glycol monomethyl ether (DPGME), diethylene glycol monomethyl ether (DEGME), butyl diglycol (BDG) and 3-methoxyl methyl butanol (MMB), tripropylene glycol methyl ether, propylene glycol propyl ether and diethylene gycol n-butyl ether; and polyols, such as, ethylene glycol, propylene glycol (PG), 1,4 butanediol, and glycerol; and cyclic alcohols, such as tetrahydrofuryl alcohol and benzyl alcohol and mixtures thereof; from about 5 to about 90% by wt. of at least one alkanolamine; from about 0.05 or 0.1 to about 20% by wt. of at least one polyfunctional organic acid; and from about 0.1 to about 10% by wt. of at least one phenol-type corrosion inhibitor that may be selected from, or selected from group consisting of, gallic acid, t-butyl catechol, catechol, 2,3-dihydroxybenzoic acid, and resorcinol, wherein the composition is substantially free or free of hydroxylamine and/or substantially free or free of quaternary ammonium hydroxides. The compositions disclosed herein are useful for removing, among other things, residue and photoresist from a semiconductor substrate during the manufacture of a microelectronic device.

Water

The cleaning compositions of the present invention comprise water. In the present invention, water functions in various ways such as, for example, to dissolve and/or lift-off one or more solid components of the composition, as a carrier of the components, as an aid to facilitate the removal of residues, and as a diluent. Preferably, the water employed in the cleaning composition is de-ionized (DI) water.

It is believed that, for most applications, water will comprise, for example, from about 5 to about 60% by wt. of the composition. Other preferred embodiments of the present invention could comprise from about 5 to about 40% by wt. of water. Yet other preferred embodiments of the present invention could comprise from about 10 to about 30% by wt., or 10 to about 25% by wt, or from about 5 to about 30% by wt, or from about 5 to about 15% by wt, or 12 to about 28% by wt of water. In other embodiments, the amount of water can be an amount in any weight percent range defined by any combination of the following weight percents: 5, 7, 10, 12, 15, 18, 20, 22, 25, 28, 30, 35, 40, 50 and 60.

Water-Miscible Organic Solvent

The compositions disclosed herein also comprise at least one water-miscible organic solvent. Examples of water-miscible organic solvents that can be employed in the compositions of this invention include any one or more of the following types of solvents pyrrolidones, sulfonyl-containing solvents, acetamides, glycol ethers, polyols, cyclic alcohols and mixtures thereof. Cyclic alcohols are alcohols having a 5- or 6-membered carbon ring. The carbon ring may be aromatic or aliphatic and may have only carbons forming the ring or may have one or more heteroatoms in the ring. An example of pyrrolidones includes N-methyl pyrrolidone (NMP). Examples of sulfonyl-containing-solvents include sulfolane and dimethylsulfoxide (DMSO). An example of acetamides includes dimethylacetamide (DMAC). Examples of glycol ethers include diproylene glycol monomethyl ether (DPGME), diethylene glycol monomethyl ether (DEGME), butyl digycol (BDG), 3-methoxyl methyl butanol (MMB), tripropylene glycol methyl ether, propylene glycol propyl ether and diethylene gycol n-butyl ether (e.g. commercially available under the trade designation Dowanol® DB). Examples of polyols include ethylene glycol, propylene glycol, 1,4-butanediol, and glycerol. Examples of cyclic alcohols include tetrahydrofurfuryl alcohol and benzyl alcohol. The solvents may be used alone or in any mixture of types of solvents or solvents thereof. Preferred solvents include ethylene glycol, propylene glycol, benzyl alcohol, dimethyl sulfoxide, dimethylacetamide, diproylene glycol monomethyl ether, n-methyl pyrrolidone, tetrahydrofurfuryl alcohol, and mixtures thereof. In some embodiments, the solvents may be selected from dimethyl sulfoxide, dimethylacetamide, diproylene glycol monomethyl ether, n-methyl pyrrolidone (NMP), 3-methoxyl methyl butanol (MMB), and diethylene glycol.

In other preferred embodiments, the water-miscible organic solvent is selected from, or selected from the group consisting of: n-methyl pyrrolidone (NMP), ethylene glycol, propylene glycol, benzyl alcohol, dimethyl sulfoxide, diproylene glycol monomethyl ether, tetrahydrofurfuryl alcohol, and mixtures thereof. N-methyl pyrrolidone (NMP) and dimethylsulfoxide are the most preferred water-miscible organic solvents.

In other embodiments, the water-miscible organic solvent is selected from, or selected from the group consisting of, N-methyl pyrrolidone (NMP), DMSO, dimethylacetamide (DMAC), diproylene glycol monomethyl ether (DPGME), ethylene glycol, propylene glycol (PG), and mixtures thereof. Alternatively, some embodiments may be substantially free or free of any of the just-listed class or individual species of solvents, alone or in any combination, for examples, the cleaning compositions of this invention may be substantially free or free of pyrrolidones, or sulfonyl-containing-solvents, or acetamides, or glycol ethers, or polyols and/or cyclic alcohols or the cleaning compositions of this invention may be substantially free or free of, for examples, ethylene glycol and/or propylene glycol and/or THFA and/or DGME and/or MMB.

For most applications, the amount of water-miscible organic solvent in the composition may be in a range having start and end points selected from the following list of weight percents: 10, 15, 17, 20, 22, 25, 27, 29, 30, 31, 33, 35, 37, 38, 40, 42, 45, 48, 50, 53, 55, 60, 70, 80, and 90. Examples of such ranges of solvent include from about 10% to about 90% by weight; or from about 10% to about 60% by weight; or from about 20% to about 60% by weight; or from about 10% to about 50% by weight; or from about 10% to about 40% by weight; or from about 10% to about 30% by weight; or from about 5% to about 30% by weight, or from 5% to about 15% by weight from about 10% to about 20% by weight; or from about 30% to about 70%, or from about 30% to about 50% by weight; or from about 20% to about 50% by weight of the composition.

Alkanolamine

The compositions disclosed herein also comprise at least one alkanolamine.

The at least one alkanolamine functions to provide a high pH alkaline environment for dissolving and lifting-off photoresist or post etch residue as well as to function as an electron-rich agent to attack post etch residue and photoresist aiding in dissolving these unwanted materials. The pH of the cleaning compositions of this invention are preferably greater than 9, or greater than 10, or from about 9 to about 13, or from about 9.5 to about 13, or from about 10 to about 13, or from about 10 to about 12.5, or from about 10 to about 12.

Suitable alkanolamine compounds include the lower alkanolamines which are primary, secondary and tertiary amines having from 1 to 10 carbon atoms. Examples of such alkanolamines include N-methylethanolamine (NMEA), monoethanolamine (MEA), diethanolamine, mono-, di- and triisopropanolamine, 2-(2-aminoethylamino)ethanol, 2-(2-aminoethoxy)ethanol, triethanolamine, N-ethyl ethanolamine, N,N-dimethylethanolamine, N,N-diethyl ethanolamine, N-methyl diethanolamine, N-ethyl diethanolamine, cyclohexylaminediethanol, and mixtures thereof.

In some embodiments, the alkanolamine is selected from, or selected from the group consisting of, methanolamine, triethanolamine (TEA), diethanolamine, N-methylethanolamine, N-methyl diethanolamine, diisopropanolamine, monoethanolamine (MEA), amino(ethoxy) ethanol (AEE), monoisopropanol amine, cyclohexylaminediethanol, and mixtures thereof. In some embodiments, the alkanolamine is selected from triethanolamine (TEA), N-methylethanolamine, monoethanolamine (MEA), amino(ethoxy) ethanol (AEE), monoisopropanol amine and mixtures thereof. In other embodiments the alkanlamine is selected from at least one of N-methylethanolamine, or monoethanolamine (MEA), or mixtures thereof.

The amount of the alkanolamine compound in the composition will, for the most applications, comprise weight percents within a range having start and end points selected from the following group of numbers: 5, 7, 8, 10, 12, 15, 20, 25, 27, 30, 33, 35, 37, 40, 43, 45, 47, 50, 52, 55, 57, 60, 63, 65, 67, 70, 80, and 90. Examples of ranges of alkanolamine compound in the compositions of this invention may be comprise from about 10% to about 70% by weight of the composition, specifically, about 20% to about 60% by weight of the composition. In some embodiments, the at least one alkanolamine compound comprises from about 10% to about 65% weight percent and, more specifically, from about 10 to about 60%, or from about 10 to about 50%, or from about 15 to about 55%, or from about 25 to about 55%, or from about 5 to about 15%, or from about 25 to about 55%, or from about 30 to about 50%, or from about 35 to about 50% by weight of the composition.

Polyfunctional Organic Acid

Compositions disclosed herein comprise at least one polyfunctional organic acid. As used herein, the term “polyfunctional organic acid” refers to an acid or a multi-acid that has more than one carboxylic acid group or at least one carboxylic acid group and at least one hydroxyl group, including but not limited to, (i) dicarboxylic acids (such as oxalic acid, malonic acid, malic acid, tartaric acid, succinic acid et al); dicarboxylic acids with aromatic moieties (such as phthalic acid et al), and combinations thereof; (ii) tricarboxylic acids (such as propane-1,2,3-tricarboxylic acid, citric acid et al), tricarboxylic acids with aromatic moieties (such as trimellitic acid, et al), and combinations thereof; (iii) tetracarboxylic acid such as, for example, ethylenediaminetetraacetic acid (EDTA); and (iv) acids having at least one hydroxyl (—OH) group in addition to the at least one carboxylic acid group, (excluding phenolic acids), for examples, lactic acid, gluconic acid and glycolic acid. The polyfunctional organic acid component primarily functions as a metal corrosion inhibitor and/or a chelating agent.

Preferred polyfunctional organic acids include, for example, those that have at least three carboxylic acid groups. Polyfunctional organic acids having at least three carboxylic acid groups are highly miscible with aprotic solvents. Examples of such acids include tricarboxylic acids (e.g., citric acid, 2-methylpropane-1,2,3-triscarboxylic, benzene-1,2,3-tricarboxylic [hemimellitic], propane-1,2,3-tricarboxylic [tricarballylic], 1,cis-2,3-propenetricarboxylic acid [aconitic], and the like), tetracarboxylic acids (e.g., butane-1,2,3,4-tetracarboxylic, cyclopentanetetra-1,2,3,4-carboxylic, benzene-1,2,4,5-tetracarboxylic [pyromellitic], and the like), pentacarboxylic acids (e.g., benzenepentacarboxylic), and hexacarboxylic acids (e.g., benzenehexacarboxylic [mellitic]), and the like. Citric acid, as well as other polyfunctional organic acids suitable for use in the compositions disclosed herein, functions as a chelating agent for aluminium. Citric acid, for example, is a tetradentate chelating agent and the chelation of citric acid and aluminium makes it an effective corrosion inhibitor of aluminium.

It is believed that the amount of polyfunctional organic acid (neat) in the compositions of the present disclosure will, for the most applications, comprise weight percents within a range having start and end points selected from the following group of numbers: 0.05, 0.07, 0.1, 0.3, 0.5, 0.7, 1, 1.2, 1.5, 1.7, 2, 2.3, 2.5, 2.7, 3, 3.5, 4, 4.5, 5, 10, 13, 15, 17 and 20, for examples, from about 0.05 wt % to about 20 wt %, or from about 0.05 wt % to about 15 wt %, or from about 0.05 wt % to about 10 wt %, or from about 0.1 wt % to about 1.5 wt %, or from about 0.5 wt % to about 3.5 wt %, or from about 0.1 wt % to about 5 wt %, or from about 0.1 wt % to about 10 wt %, or from about 0.5 wt % to about 7.5 wt %, or from about 1 wt % to about 5 wt %.

Corrosion Inhibitor

The compositions disclosed herein include at least one phenol-type corrosion inhibitor. The phenol-type inhibitors include, for examples, t-butyl catechol, catechol, gallic acid, 2,3-dihydroxybenzoic acid, and resorcinol, or mixtures thereof. The phenol-type inhibitors typically act as corrosion inhibitors for aluminium. The at least one phenol-type inhibitors may be selected from, or may be selected from the group consisting of, t-butyl catechol, catechol, gallic acid, 2,3-dihydroxybenzoic acid, and resorcinol. The at least one phenol-type inhibitor in the compositions disclosed herein, functions to prevent metal corrosion by scavenging oxygen-containing corrosive species in the medium. In the alkaline solution, oxygen reduction is a cathodic reaction and the corrosion can be controlled by decreasing the oxygen content using scavengers. In some embodiments the phenol-type inhibitors will include catechol, gallic acid and/or resorcinol.

It is believed that for most applications, the phenol-type corrosion inhibitors, which may be at least one selected from, or selected from the group consisting of catechol, t-butyl catechol, gallic acid, 2,3-dihydroxybenzoic acid, and resorcinol, will comprise a weight percent of the composition within a range having start and end points selected from: 0.1, 1, 2, 2.5, 3, 3.5, 4, 4.5, 5, 6, 6.5, 7, 8, 9 and 10. For examples, the cleaning composition may comprise the at least one phenol-type inhibitor in an amount from about 0.1 to about 10%; or from about 0.1 to about 7%, or from about 1 to about 7%, or from about 2 to about 7%, or from about 0.1 to about 6%, or from about 1 to about 5% by weight of the cleaning composition.

Auxiliary Metal Chelating Agent (Optional)

An optional ingredient that can be employed in the cleaning compositions of the present invention is an auxiliary metal chelating agent. The chelating agent can function to increase the capacity of the composition to retain metals in solution and to enhance the dissolution of metallic residues. Thus, although the at least one phenol-type corrosion inhibitor that may be selected from catechol, t-butyl catechol, gallic acid, 2,3-dihydroxybenzoic acid, and resorcinol functions as an aluminum chelating agent, the auxiliary chelating agents may function to chelate metals other than aluminum. Typical examples of such auxiliary chelating agents useful for this purpose are the following organic acids and their isomers and salts: (ethylenedinitrilo)tetraacetic acid (EDTA), butylenediaminetetraacetic acid, (1,2-cyclohexylenedinitrilo-)tetraacetic acid (CyDTA), diethylenetriaminepentaacetic acid (DETPA), ethylenediaminetetrapropionic acid, (hydroxyethyl)ethylenediaminetriacetic acid (HEDTA), N, N,N′, N′-ethylenediaminetetra(methylenephosphonic) acid (EDTMP), triethylenetetraaminehexaacetic acid (TTHA), and 1,3-diamino-2-hydro)rypropane-N,N,N′,N′-tetraacetic acid (DHPTA). It is recognized that the just-listed chelating agents are polyfunctional organic acids and that EDTA is listed as an example of a useful polyfunctional organic acid as well as a chelating agent. Note, if a chelating agent is present in the cleaning compositions of this invention, it will differ from the one or more polyfunctional acids and phenol-containing inhibitors in the composition.

It is believed that, for most applications, the auxiliary chelating agent, if used, will be present in the composition in a weight percent of the composition within a range having start and end points selected from the following group of numbers: 0, 0.1, 1, 2, 2.5, 3, 3.5, 4, 4.5, 5, 6, 6.5, 7, 8, 9, 10, 12, 14, 16, 18 and 20. For examples, the chelating agent may be present in an amount of from 0 to about 5% by weight, or from about 0.1 to about 20% by weight, or from about 2 to about 10% by weight or from about 0.1 to 2% by weight of the composition.

Compositions disclosed herein are preferably substantially free or free of hydroxylamine or HA derivatives. Additionally, compositions of this invention may be substantially free or free of one or more of the following in any combination: abrasives, inorganic acids, inorganic bases, surfactants, oxidizers, peroxides, quinones, fluoride-containing compounds, chloride-containing compounds, phosphorous-containing compounds, metal-containing compounds, quaternary ammonium hydroxides, quaternary amines, amino acids, ammonium hydroxide, alkyl amines, aniline or aniline derivatives, and metal salts. In some embodiments, for an example, the compositions of the invention are substantially free or free of hydroxylamine and tetramethylammonium hydroxide.

In one embodiment of the present invention, there is provided a composition useful for removing residue and photoresist from a semiconductor substrate comprising, consisting essentially of, or consisting of: from about 30 to about 40% by wt. of NMP or DMSO; from about 40 to about 50% by wt. of an alkanolamine selected from the group consisting of N-methylethanolamine, monoethanolamine, and a mixture thereof; from about 0.5 to about 3.5% by wt. of citric acid; from about 2.0 to about 4% by wt. of at least one selected from, or selected from the group consisting of, catechol, t-butyl catechol, gallic acid, 2,3-dihydroxybenzoic acid, and resorcinol; and the remainder being water, wherein the composition is substantially free or free of hydroxylamine, and wherein the total weight percents of the components equal 100 percent.

In another embodiment of the present invention, there is provided a composition useful for removing residue and/or photoresist from a semiconductor substrate comprising, consisting essentially of, or consisting of: from about 5 to about 50% by wt. of water; from about 20 to about 60% by wt. of a water-miscible organic solvent selected from, or selected from the group consisting of, N-methyl pyrrolidone (NMP), DMSO, dimethylacetamide (DMAC), diproylene glycol monomethyl ether (DPGME), ethylene glycol, propylene glycol (PG), and mixtures thereof; from about 20 to about 70% by wt. of an alkanolamine; from about 0.1 to about 10% by wt. of at least one polyfunctional organic acid; and from about 0.1 to about 10% by wt. of at least one phenol-type corrosion inhibitor selected from, or selected from the group consisting of, catechol, t-butyl catechol, gallic acid, 2,3-dihydroxybenzoic acid, and resorcinol, wherein the composition is substantially free or free of hydroxylamine, and wherein the total weight percents of the components equal 100 percent.

In another embodiment of the present invention, there is provided a composition useful for removing residue and/or photoresist from a semiconductor substrate comprising, consisting essentially of, or consisting of: from about 10 to about 30% or from about 5 to about 15% by wt. of water; from about 20 to about 60% by wt. of a water-miscible organic solvent selected from, or selected from the group consisting of, N-methyl pyrrolidone (NMP), DMSO, dimethylacetamide (DMAC), diproylene glycol monomethyl ether (DPGME), ethylene glycol, propylene glycol (PG), and mixtures thereof; from about 20 to about 50% by wt. of at least one alkanolamine; from about 0.1 to about 10% by wt. of at least one polyfunctional organic acid; and from about 0.1 to about 5% by wt. of at least one phenol-type corrosion inhibitor selected from, or selected from the group consisting of, catechol, t-butyl catechol, gallic acid, 2,3-dihydroxybenzoic acid, and resorcinol, wherein the composition is substantially free or free of hydroxylamine, and wherein the total weight percents of the components equal 100 percent.

In another embodiment of the present invention, there is provided a composition useful for removing residue and/or photoresist from a semiconductor substrate comprising, consisting essentially of, or consisting of: from about 5 to about 25% by wt. of water; from about 20 to about 60% by wt. of a water-miscible organic solvent; from about 20 to about 50% by wt. of at least one alkanolamine; from about 0.1 to about 10% by wt. of at least one polyfunctional organic acid; and from about 0.1 to about 5% by wt. of at least one phenol-type corrosion inhibitor selected from, or selected from the group consisting of, catechol, t-butyl catechol, gallic acid, 2,3-dihydroxybenzoic acid, and resorcinol, wherein the composition is substantially free or free of hydroxylamine, and wherein the total weight percents of the components equal 100 percent.

The cleaning compositions of the present invention are typically prepared by mixing the components together in a vessel at room temperature until all solids have dissolved in the liquid medium (i.e., water, solvent, or a mixture thereof).

The cleaning composition of the present invention can be used to remove from a substrate undesired residue and photoresist. It is believed that the composition can be used to particularly good advantage in cleaning a semiconductor substrate on which residue and/or photoresist is deposited or formed during the process for manufacturing semiconductor devices; examples of such residue include resist compositions in the form of films (both positive and negative) and etching deposits formed during dry etching, as well as chemically degraded resist films. The use of the composition is particularly effective when the residue to be removed is a resist film and/or an etching deposit on a semiconductor substrate having a metal film-exposed surface. Examples of substrates that can be cleaned by use of the composition of the present invention without attacking the substrates themselves include metal substrates, for example: aluminum titanium/tungsten; aluminum/silicon; aluminum/silicon/copper; silicon oxide; silicon nitride; aluminum nitride, and gallium/arsenide. Such substrates typically include residues comprising photoresists and/or post etch deposits.

Examples of resist compositions that can be effectively removed by use of the cleaning composition of the present invention include photoresists containing esters or ortho-naphthoquinones and novolak-type binders and chemically amplified resists containing blocked polyhydroxystyrene or copolymers of polyhydroxystyrene and photoacid generators. Examples of commercially available photoresist compositions include Clariant Corporation AZ 1518, AZ 4620, Shipley Company, Inc. photoresists, S1400, APEX-E™ positive DUV, UVS™ positive DUV, Megaposit™ SPR™ 220 Series; Megaposit™ SPR™ 3600 Series; JSR Microelectronics photoresists KRF® Series, ARF® Series; and Tokyo Ohka Kogyo Co., Ltd. Photoresists TSCR Series and TDUR-P/N Series.

The cleaning compositions disclosed herein can be used to remove post-etch and ash, other organic and inorganic residues as well as polymeric residues from semiconductor substrates at relatively low temperatures with little corrosive effect, for example, low metal etch rates. The cleaning compositions of this invention, when used in the method of this invention, typically provide etch rates for some metals, for examples, Al, AlCu and/or W that are less than 2 Å/min when the cleaning compositions are at a temperature of less than or equal to 60° C., or less than 1 Å/min at a temperature of less than or equal to 60° C. The cleaning compositions of this invention, when used in the method of this invention, typically provide etch rates for some metals, for example, AlN, that are less than 4 Å/min when the cleaning composition contacts the substrates at a temperature less than or equal to 60° C., or less than 1 Å/min at a temperature less than or equal to 50° C.

The cleaning compositions should be applied to the surface for a period of time sufficient to obtain the desired cleaning effect. The time will vary depending on numerous factors, including, for example, the nature of the residue, the temperature of the cleaning composition and the particular cleaning composition used. In general, the cleaning composition can be used, for example, by contacting the substrate at a temperature of from about 25° C. to about 85° C., or from about 45° C. to about 65° C., or from about 55° C. to about 65° C. for a period of time ranging from about 1 minute to about 1 hour followed by one or more rinsing steps (solvent and/or water) to rinse the cleaning composition from the substrate and drying the substrate.

Accordingly, in another aspect, the present invention provides a method for removing residue from a substrate, the method comprising the steps of: contacting the substrate with a cleaning composition as described above; rinsing the substrate with an organic solvent followed by water; and drying the substrate.

The contacting step can be carried out by any suitable means such as, for example, immersion, spray, or via a single wafer process; any method that utilizes a liquid for removal of photoresist, ash or etch deposits and/or contaminants can be used.

The rinsing step with de-ionized water typically follows an intermediate organic solvent rinse and is carried out by any suitable means, for example, rinsing the substrate with the de-ionized water by immersion or spray techniques. Organic solvent rinse may comprise isopropyl alcohol or NMP. The water rinse may be with carbonated water. Moreover, prior art amine-based cleaning compositions etch silicon from the substrate. Use of the compositions of the present invention minimize damage to the silicon in such substrates.

The drying step is carried out by any suitable means, for example, isopropyl alcohol (IPA) vapor drying or by heat or centripetal force.

It will be appreciated by those skilled in the art that the cleaning compositions of the present invention may be modified to achieve optimum cleaning without damaging the substrate so that high throughput cleaning can be maintained in the manufacturing process. For example, one skilled in the art would appreciate that, for example, modifications to the amounts of some or all of the components may be made depending upon the composition of the substrate being cleaned, the nature of the residue to be removed, and the particular process parameters used.

Although the present invention has been principally described in connection with cleaning semiconductor substrates, the cleaning compositions of the invention can be employed to clean any substrate that includes organic and inorganic residues.

### EXAMPLES

The following examples are provided for the purpose of further illustrating the present invention but are by no means intended to limit the same.

### General Procedure for Preparing the Cleaning Compositions

All compositions which are the subject of the present Examples were prepared by mixing 500 g of material in a 600 mL beaker with a Teflon-coated stir bar and stored in a plastic bottle. The liquid components can be added in any order prior to the solid component.

### Compositions of the Substrate

Substrates used in the present Examples were Al metal lines and Al pads. The Al metal line or Al pads substrate consisted of one or more of the following layers AlN, W, TiN, Al, TiN, Ti metallurgy that was/were patterned and etched by reactive ion etching (RIE). Photoresist was not removed by oxygen plasma ashing. No ash step was used and the compositions evaluated herein were used to clean the photoresist without any undesired etching of contacted materials. The photoresist used in the examples was MEGAPOSIT™ SPR3622, a positive photoresist from Dow.

### Processing Conditions

Cleaning tests were processed in a beaker filled with 100 mL of the cleaning compositions with a round Teflon stir bar. The cleaning compositions were heated to the desired temperature on a hot plate if necessary. Wafer segments approximately ½″×½″ in size were placed in a holder and immersed in the compositions at desired temperature for desired time.

Upon completion, the segments were then rinsed with intermediate solution of NMP or IPA for 3 minutes followed by DI water rinse in a overflow bath and subsequently dried using compressed nitrogen gas. They were then analyzed for cleanliness using SEM microscopy.

### Etch Rate Measurement Procedure

Coupons of the blanket Al or W wafer were measured for metal layer thickness by measuring the resistivity of the layer by employing a ResMap™ model 273 resistivity instrument from Creative Design Engineering, Inc. (Long Island City, N.Y.). The thickness of metal layer of coupons were initially measured. The coupons were then immersed in the composition at the desired temperature for desired time. After processing, the coupons were removed from the composition, rinsed with de-ionized water and dried and the thickness of the metal layer was again measured. A graph of the change in thickness as a function of immersion time was made and the etch rate in Angstroms/min was determined from the slope of the curve.

Aluminium nitride (AlN) etch rates were evaluated by measuring the thickness change which was measured by employing a method of Filmtek ellipsometry. The thickness of AlN is measured prior to and after the immersion of the compositions under desired process conditions. A graph of the change in thickness as a function of immersion time was made and the etch rate in Angstroms/min was determined from the slope of the curve.

Clean results were checked by optical microscope and scanning electron microscope (SEM). Resist removal is defined as “clean” if all resist was removed from the wafer coupon surface; as “mostly clean” if at least 95% of the resist was removed from the surface; “partly clean” if about 80% of the resist was removed from the surface.

### Results

The following examples describe cleaning compositions for the removal of photoresist and anti-reflective coating (ARC) from substrates for semiconductor devices. The solutions described contain DMSO, NMP, NMEA or MEA, water, citric acid, and/or catechol or other components as indicated in the Tables below.

The effect of corrosion inhibitors on metal etch rates showed in Table 1. Addition of citric acid and catechol improved the cleaning performance of photoresist and ARC from substrate. Both citric acid and catechol decreased metal etch rates with the best results when used together.

TABLE 1
The effect of corrosion inhibitors combination in formulation

| | Comparable | Comparable | Comparable | | |
|---|---|---|---|---|---|
| Examples | example 1 | example 2 | example 3 | 19L | 19M |
| NMP | 39.7 | 39.2 | 37.7 | 37 | 37.7 |
| MEA | 45 | 45 | 45 | 43 | 44 |
| NMEA | | | | | |
| Water | 15.3 | 15.3 | 15.3 | 17.2 | 15.3 |
| Catechol | | | 2 | 2 | 2 |
| Citric acid | | 0.5 | | 0.8 | 1 |
| pH | 11.7 | 11.5 | 11.3 | 11.0 | 11.1 |
| AICu Å/min | 5.55 | 0.58 | 2.88 | 1.42 | 0.55 |
| @60° C. | | | | | |
| W Å/min | 1.87 | 0.96 | 0.79 | 0.78 | 0.83 |
| @60° C. | | | | | |
| AIN Å/min | 25.7 | 2.53 | 24.1 | 5.86 | 3.7 |
| @60° C. | | | | | |
| Cleaning | Partly clean | Clean | Clean | Clean | Clean |
| @60° C., | | | | | |
| 10 min | | | | | |

The effect of different organic solvents on metal etch rates showed in Table 2. At same processing condition, the solvents had slight effect on metal etch rates.

TABLE 2
The effect of different solvents on etch rates

| Examples | 1B | 19A | 19B | 19C | 19D |
|---|---|---|---|---|---|
| NMP | 38.2 | 37.7 | | | |
| DMSO | | | 45.5 | | |
| MMB | | | | 45.5 | |
| DEG | | | | | 45.5 |
| MEA | 44 | 44 | 41 | 41 | 41 |
| Water | 17.8 | 15.3 | 10.5 | 10.5 | 10.5 |
| Catechol | | 2 | 2 | 2 | 2 |
| Citric acid | | 1 | 1 | 1 | 1 |
| pH | 11.59 | 11.1 | 11.2 | 11.1 | 11.0 |
| AICu Å/min @60° C. | 4.8 | 0.55 | 0.16 | 1.05 | 1.19 |
| W Å/min @60° C. | 2.7 | 0.83 | 0.68 | 1.05 | 0.51 |
| AIN Å/min @60° C., | | 3.7 | 2.4 | 4.2 | 6.5 |
| 30 min | | | | | |

The effect of different polyfunctional organic acid on metal etch rates is showed in Table 3. Compared to the comparable example 2, the different polyfunctional organic acids decreased the metal etch rates.

TABLE 3
The effect of polyfunctional organic acid on etch rates

| Examples | 19E | 19F | 19G | 19H |
|---|---|---|---|---|
| DMSO | 38 | 38 | 38 | 38 |
| MEA | 46.5 | 46.5 | 46.5 | 46.5 |
| Water | 12.5 | 12.5 | 12.5 | 12.5 |
| Catechol | 2 | 2 | 2 | 2 |
| Citric acid | 1 | | | |
| Lactic acid | | 1 | | |
| Gluconic acid | | | 1 | |
| EDTA | | | | 1 |
| pH | 11.22 | 11.18 | 11.33 | 11.18 |
| AICu Å/min @60° C. | 0.15 | 0.45 | 0.21 | 0.14 |
| W Å/min @60° C. | 0.4 | 0.55 | 0.38 | 0.36 |
| AIN Å/min @60° C. | 1.72 | 11.39 | 4.11 | 8.1 |

The effect of phenol-type corrosion inhibitor on metal etch rates was tested. The addition of the phenol-type inhibitors decreased the metal etch rates, that is, the AlCu and W etch rates as shown in Table 4.

TABLE 4
The effect of phenol-type corrosion inhibitor on etch rates

| Examples | 19I | 19J | 19K |
|---|---|---|---|
| DMSO | 39.2 | 39.2 | 39.2 |
| MEA | 40.3 | 40.3 | 40.3 |
| Water | 17.5 | 17.5 | 17.5 |
| Catechol | 2 | | |
| Gallic acid | | 2 | |
| Resorcinol | | | 2 |
| Citric acid | 1 | 1 | 1 |
| pH | 11.06 | 10.99 | 10.6 |
| AICu Å/min @60° C. | 0.45 | 0.04 | 0.16 |
| W Å/min @60° C. | 0.46 | 0.51 | 0.47 |
| AIN Å/min @60° C. | 3.9 | 1 | 4.9 |

The formulations listed in Table 5 can efficiently remove the photoresist and ARC. The addition of citric acid can dramatically reduce the Al—Cu and W etch rates

TABLE 5
Effect of citric acid concentration

| Example | 1B | 1B-1 | 1B-2 | 1B-3 |
|---|---|---|---|---|
| NMP | 38.2 | 38 | 37.7 | 38.1 |
| MEA | 44 | 44 | 44 | 44 |
| H₂O | 17.8 | 17.8 | 17.8 | 17.8 |
| Citric acid | 0 | 0.2 | 0.5 | 0.1 |
| pH | 11.59 | 11.44 | 11.28 | 11.54 |
| AI-Cu ER (Å/min), 60° C. | 4.8 | 0.36 | 0.05 | 0.25 |
| W ER (Å/min), 60° C. | 2.7 | 1.26 | 0.92 | 1.05 |
| Stripping performance | partly clean | clean | clean | clean |
| (60° C., 10 min) | | | | |

### Example 2: Catechol as a Corrosion Inhibitor

Table 3 shows that catechol is able to serve as a co-inhibitor of corrosion for both Al—Cu and W.

TABLE 6
Effect of catechol concentration

| Example | 1B-4 | 1B-2A | 1B-2B | 1B-2C |
|---|---|---|---|---|
| NMP | 38 | 37 | 36 | 34 |
| MEA | 44 | 44 | 44 | 44 |
| H₂O | 17.5 | 17.5 | 17.5 | 17.5 |
| Catechol | | 1 | 2 | 4 |
| Citric acid | 0.5 | 0.5 | 0.5 | 0.5 |
| pH | 11.16 | 11.07 | 10.96 | 10.76 |
| AI-Cu ER (Å/min), 60° C. | 0.24 | 1.26 | 0.38 | 0.03 |
| W ER (Å/min), 60° C. | 1 | 0.83 | 0.92 | 0.9 |
| Stripping performance | clean | clean | clean | clean |
| (60° C., 10 min) | | | | |

### Example 3: Optimization of Corrosion Inhibitors

Table 7 shows that at an initial catechol concentration of 2 wt. %, the increase in citric acid concentration decreases the metal etch rates for both Al—Cu and W.

TABLE 7
Effect of citric acid concentration in the presence of catechol

| Example | 1D | 1D-1 | 1D-2 |
|---|---|---|---|
| NMP | 38.7 | 38.2 | 37.7 |
| MEA | 44 | 44 | 44 |
| H₂O | 15.3 | 15.3 | 15.3 |
| Catechol | 2 | 2 | 2 |
| Citric acid | 0 | 0.5 | 1 |
| pH | 11.16 | 11.07 | 10.96 |
| AI-Cu ER (Å/min), 60° C. | 2.4 | 1.4 | 0.4 |
| W ER (Å/min), 60° C. | 0.8 | 0.8 | 0.9 |
| Stripping performance | clean | clean | Clean |
| (60 C., 10 min) | | | |

### Example 4: Evaluation of Alkanolamine

Referring to Table 8, the following results show that either MEA or NMEA are effective in the compositions disclosed herein. Example 1A showed the excellent metal compatibility. Table 9 showed the AlN surface roughness after 1 A treatment did not change, consistent to its very low AlN etch rate.

TABLE 8
Effect of different of alkanolamines

| Example | 1E | 1F | 1A | 1H |
|---|---|---|---|---|
| NMP | 37 | 37 | 33 | 33 |
| MEA | 43 | | | 13.8 |
| NMEA | | 42.6 | 48 | 34.2 |
| H₂O | 17.2 | 17.5 | 12.3 | 12.3 |
| Catechol | 2 | 2 | 4 | 4 |
| Citric acid | 0.84 | 0.9 | 2.7 | 2.7 |
| Cleaning @60° C., 10 min | Clean | Clean | Clean | Clean |
| AI-Cu Å/min @50° C. | 0.23 | 0.035 | 0.03 | 0.05 |
| W ER Å/min @50° C. | 0.47 | 0.39 | 0.42 | 0.51 |
| AIN Å/min @50° C. | 1.53 | 1.92 | 0.27 | 0.34 |
| AI-Cu Å/min @60° C. | | | 0.14 | 0.10 |
| W ER Å/min @60° C. | | | 0.95 | 0.91 |
| AIN Å/min @60° C. | | | 0.68 | 1.08 |

TABLE 9
Surface roughness of AIN blanket films

| Surface roughness | Rq, nm | Ra, nm |
|---|---|---|
| AIN control | 1.36 | 1.08 |
| AIN processed by 1A | 1.41 | 1.12 |

### Example 5: Optimization of Water Content

Table 10 illustrates that the optimized water content for some embodiments may be in the range of from about 10-18%.

TABLE 10
The effect of water concentration on cleaning

| Component | 1A | 1A-1 | 1A-2 |
|---|---|---|---|
| NMP | 33 | 35 | 39 |
| NMEA | 48 | 48 | 48 |
| H₂O | 12.3 | 10.3 | 6.3 |
| Catechol | 4 | 4 | 4 |
| Citric acid | 2.7 | 2.7 | 2.7 |
| Cleaning performance | Clean | clean | partly clean |
| (50° C., 15 min) | | | |

The foregoing examples and description of the preferred embodiments should be taken as illustrating, rather than as limiting the present invention as defined by the claims. As will be readily appreciated, numerous variations and combinations of the features set forth above can be utilized without departing from the present invention as set forth in the claims. Such variations are not regarded as a departure from the spirit and scope of the invention, and all such variations are intended to be included within the scope of the following claims.

1. A composition useful for removing residue and photoresist from a semiconductor substrate comprising:
from about 5 to about 60% by wt. of water;
from about 10 to about 90% by wt. at least one water-miscible organic solvent selected from pyrrolidones, sulfonyl-containing solvents, acetamides, glycol ethers, polyols, cyclic alcohols, and mixtures thereof;
from about 5 to about 90% by wt. of at least one alkanolamine;
from about 0.05 to about 20% by wt. of at least one polyfunctional organic acid; and
from about 0.1 to about 10% by wt. of at least one phenol-type corrosion inhibitor,
wherein the composition is substantially free of hydroxylamine.

2. The composition of claim 1 comprising from about 10 to about 60% by wt. of said at least one water-miscible organic solvent.

3. The composition of claim 1 comprising from about 10 to about 50% by wt. of said at least one alkanolamine.

4. The composition of claim 1 comprising from about 0.1 to about 5% by wt. of said at least one polyfunctional organic acid.

5. The composition of claim 1 comprising from about 1 to about 7% by wt. of said at least one phenol-type corrosion inhibitor.

6. The composition of claim 1 comprising from about 5 to about 15% by wt. of said water.

7. The composition of claim 1, wherein said water miscible solvent is selected from N-methyl pyrrolidone (NMP), sulfolane, dimethylsulfoxide (DMSO), dimethylacetamide (DMAC), diproylene glycol monomethyl ether (DPGME), diethylene glycol monomethyl ether (DEGME), butyl digycol (BDG), 3-methoxyl methyl butanol (MMB), tripropylene glycol methyl ether, propylene glycol propyl ether, diethylene gycol n-butyl ether, ethylene glycol, propylene glycol, 1,4-butanediol, glycerol, tetrahydrofurfuryl alcohol and benzyl alcohol, and mixtures thereof.

8. The composition of claim 1, wherein said at least one water-miscible organic solvent is selected from N-methyl pyrrolidone (NMP), dimethylacetamide (DMSO), dimethylacetamide (DMAC), diproylene glycol monomethyl ether (DPGME), ethylene glycol, propylene glycol (PG), and mixtures thereof.

9. The composition of claim 1, wherein the at least one alkanolamine is selected from N-methylethanolamine (NMEA), monoethanolamine (MEA), diethanolamine, mono-, di- and triisopropanolamine, 2-(2-aminoethylamino)ethanol, 2-(2-aminoethoxy)ethanol, triethanolamine, N-ethyl ethanolamine, N,N-dimethylethanolamine, N,N-diethyl ethanolamine, N-methyl diethanolamine, N-ethyl diethanolamine, cyclohexylaminediethanol, and mixtures thereof.

10. The composition of claim 1, wherein the alkanolamine comprises N-methylethanolamine.

11. The composition of claim 1, wherein the alkanolamine comprises monoethanolamine.

12. The composition of claim 1, wherein said at least one phenol-type corrosion inhibitor is selected from t-butyl catechol, catechol, 2,3-dihydroxybenzoic acid, gallic acid, resorcinol, and mixtures thereof.

13. The composition of claim 1, wherein the at least one polyfunctional organic acid is selected from citric acid, malonic acid, malic acid, tartaric acid, oxalic acid, phthalic acid, maleic acid, ethylenedinitrilo)tetraacetic acid (EDTA), butylenediaminetetraacetic acid, (1,2-cyclohexylenedinitrilo-)tetraacetic acid (CyDTA), diethylenetriaminepentaacetic acid (DETPA), ethylenediaminetetrapropionic acid, (hydroxyethyl)ethylenediaminetriacetic acid (HEDTA) and mixtures thereof.

14. The composition of claim 1, wherein the at least one polyfunctional organic acid comprises citric acid.

15. The composition of claim 1, wherein the at least one water-miscible organic solvent comprises NMP.

16. The composition of claim 1, wherein the at least one water-miscible organic solvent comprises DMSO.

17. The composition of claim 1 further comprising at least one chelating agent, wherein said at least one chelating agent differs from said at least one corrosion inhibitor and said at least one polyfunctional acid.

18. The composition of claim 17, wherein said at least one chelating agent is present in said composition in an amount from about 0.1 to about 2 wt %.

19. The composition of claim 17, wherein said at least one chelating agent is selected from (ethylenedinitrilo)tetraacetic acid (EDTA), butylenediaminetetraacetic acid, (1,2-cyclohexylenedinitrilo-)tetraacetic acid (CyDTA), diethylenetriaminepentaacetic acid (DETPA), ethylenediaminetetrapropionic acid, (hydroxyethyl)ethylenediaminetriacetic acid (HEDTA), N, N,N′, N′-ethylenediaminetetra(methylenephosphonic) acid (EDTMP), triethylenetetraaminehexaacetic acid (TTHA), 1,3-diamino-2-hydroxypropane-N,N,N′,N′-tetraacetic acid (DHPTA), isomers or salts thereof, and mixtures thereof.

20. The composition of claim 1 having a pH value from 9 to 13.

21. A method for removing residue or photoresist from a substrate comprising at least one of aluminum-copper alloy, aluminum nitride and tungsten; the method comprising the steps of:
contacting the substrate with a cleaning composition of claim 1; and
rinsing the substrate with water.

22. The method of claim 21, wherein the temperature of the cleaning composition during the contacting step is from about 25° C. to about 85° C.

23. The method of claim 21 or 22 further comprising, prior to the step of rinsing the substrate with water, a step of rinsing the substrate with an organic solvent.

24. (canceled)

25. The method of claim 21, wherein the etch rate is less than about 1 Å/min when the temperature of cleaning composition during the contacting step is less than or equal to about 60° C.

26. (canceled)

27. (canceled)

28. (canceled)
